(19) United States
(12) Patent Application Publication
(10) Pub. No.: US 2012/0160786 A1
(43) Pub. Date: Jun. 28, 2012

(54) STRETCHABLE BRACKET FOR PLACING CIRCUIT BOARD

(75) Inventors: YAN ZHUANG, Shenzhen City (CN); LAN LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/090,232

(22) Filed: Apr. 19, 2011

(30) Foreign Application Priority Data
Dec. 25, 2010 (CN) 201010606835.3

(51) Int. Cl. H05K 7/18

(52) U.S. Cl. 211/26

(57) ABSTRACT

A stretchable bracket for placing circuit boards includes a number of upright posts and a number of connecting rods. Each upright post includes a number of supporting protrusions arranged along a lengthwise direction of the upright post for supporting the circuit boards. Each two adjacent upright posts are connected via one connecting rod. Each connecting rod includes a first connecting portion and a second connecting portion. The second connecting portion is slidable relative to the first connecting portion to stretch the connecting rod.

### BACKGROUND

1. Technical Field

The present disclosure relates to brackets and, particularly, to a stretchable bracket for placing circuit boards.

2. Description of Related Art

A circuit board is an important component of an electronic device, such as a server, or a computer etc. The circuit board usually has many electronic elements at both two sides thereof, and should be protected from static electricity. Therefore, a circuit board need to be handled and placed with care before being assembled into a casing of the electronic device.

What is needed is a stretchable bracket for placing circuit boards which can ameliorate the problem of the prior art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a schematic, isometric view of a stretchable bracket according to an exemplary embodiment.

FIG. 2 is a schematic, isometric view of the stretchable bracket of FIG. 1 with circuit boards placed thereon.

FIG. 3 is a magnified view of a connecting rod of the stretchable bracket of FIG. 1.

### DETAILED DESCRIPTION

Embodiments of the present disclosure will now be described in detail below, with reference to the accompanying drawings.

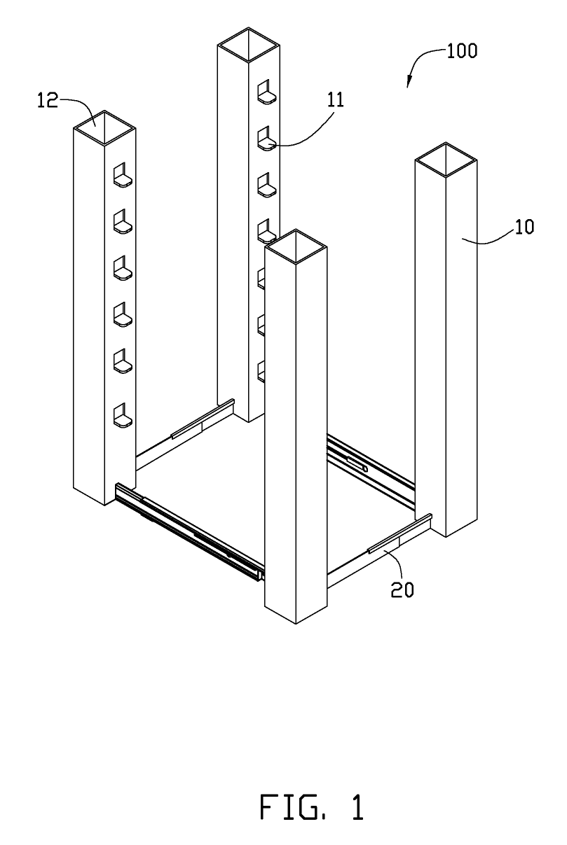

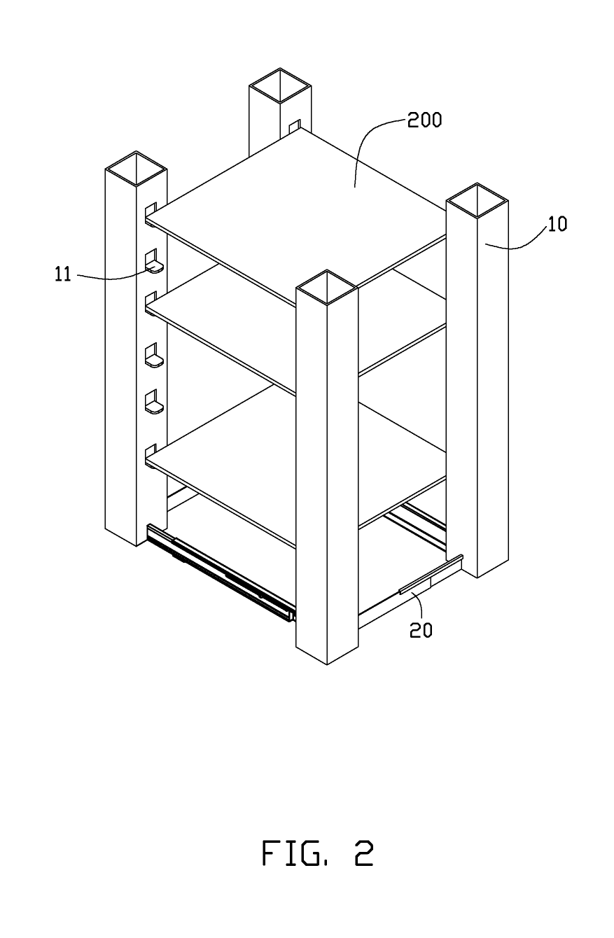

Referring to FIGS. 1 and 2, a stretchable bracket 100 according to an exemplary embodiment is shown. The stretchable bracket 100 includes four upright posts 10 and four connecting rods 20.

The upright posts 10 each has a number of supporting protrusions 11 arranged along a lengthwise direction thereof. The supporting protrusions 11 of the four upright posts 10 at the same level can cooperatively support a circuit board 200 thereon. Because the supporting protrusions 11 of the upright posts 10 are arranged along the lengthwise direction thereof, the circuit boards 200 can be stacked arrangement along the lengthwise direction of the upright posts 10, therefore, the space for placing the circuit boards 200 can be saved. It is understood, the number of the upright posts 10 is not limited to the present embodiment, the number of the upright posts 10 can also be three, five, and so on. In order that the circuit boards 20 can be placed on the stretchable bracket 100 safely, the number of the upright posts 10 is preferably larger than three.

The upright posts 10 and the supporting protrusions 11 can be made of electric conductive material, thus, the supporting protrusions 11 can be grounded via the upright posts 10 to protect the circuit boards 200 from static electricity. The upright post 10 can be integrally formed with the supporting protrusions 11. In other embodiments, the upright posts 10 can also be made of electric insulative material, and the supporting protrusions 11 can be grounded via a wire (not shown).

In the present embodiment, each of the upright posts 10 defines a latching hole 12 for connecting with the connecting rods 20. The latching hole 12 can be a through hole or a blind hole. In the present embodiment, the latching hole 12 is a through hole extending along the lengthwise direction of the upright post 10.

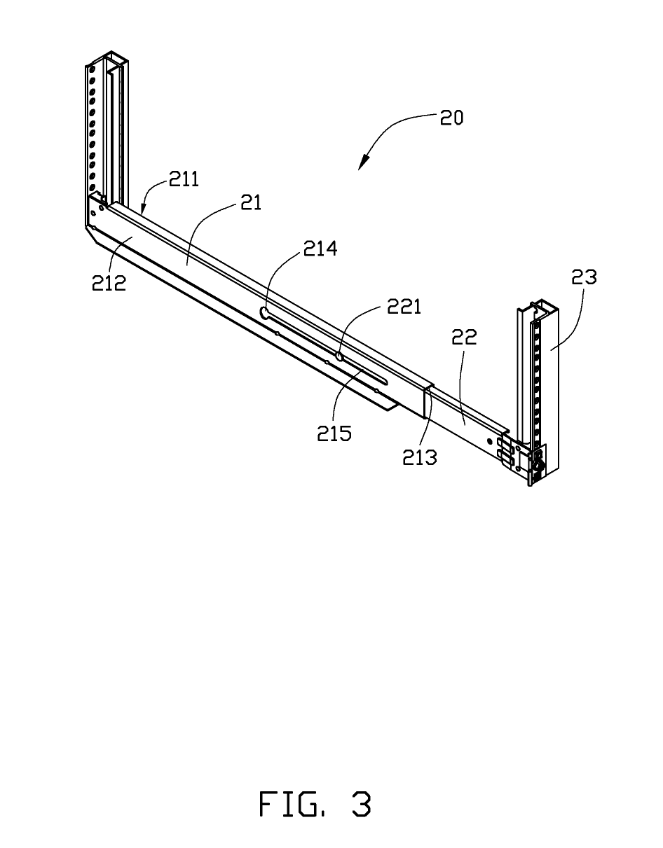

Further referring to FIG. 3, the four connecting rods 20 connect the four upright posts 10. The four connecting rods 20 are arranged in a rectangular shape, and are stretchable. Each connecting rod 20 is elongated, and perpendicularly connected two neighboring upright posts 10. The distance between the two neighboring upright posts 10 can be adjusted by stretching the connecting rod 20 connected therebetween. Each connecting rod 20 includes a first connecting portion 21, a second connecting portion 22, and two latching portions 23.

The first connecting portion 21 and the second connecting portion 22 extend along a lengthwise of the connecting rod 20. The first connecting portion 21 includes a first sidewall 211 and a second sidewall 212 opposite to the first sidewall 211. Both of the first sidewall 211 and the second sidewall 212 extend along the lengthwise of the connecting rod 20. The first connecting portion 21 defines a sliding slot 213 on the first sidewall 211. The sliding slot 213 extends along the lengthwise of the connecting rod 20. The second connecting portion 22 is received in the sliding slot 213 and is slidable along the sliding slot 213. In the present embodiment, the first connecting portion 21 further defines an assembling hole 214 and a sliding groove 215 running through the first sidewall 211 and the second sidewall 212. The sliding groove 215 extends along the lengthwise of the connecting rod 20 from the assembling hole 214. The second connecting portion 22 includes an engaging protrusion 221 facing towards the first connecting portion 21. The engaging protrusion 221 can be inserted into the assembling hole 214 and is slidable along the sliding groove 215 to prevent the second connecting portion 22 separating from the first connecting portion 21.

The two latching portions 23 are fixed to the first connecting portion 21 and the second connecting portion 22, respectively, and are arranged at two opposite ends of the connecting rod 20. The two latching portions 23 can be inserted into the latching holes 12 of the corresponding two upright posts 10, thus, the connecting rod 20 can be connected to the two upright posts 10.

In the present embodiment, because each upright post 10 has a number of supporting protrusions 11 arranged along a lengthwise direction thereof, the circuit boards 200 can be stacked along the lengthwise direction of the upright posts 10, therefore, the space for placing the circuit boards 200 can be saved. Furthermore, because the distance between each two adjacent upright posts 10 can be adjusted by stretching the connecting rod 20, the stretchable bracket 100 can be used for placing various circuit boards 200 with different sizes.

While certain embodiments have been described and exemplified above, various other embodiments will be apparent to those skilled in the art from the foregoing disclosure. The disclosure is not limited to the particular embodiments described and exemplified, and the embodiments are capable of considerable variation and modification without departure from the scope and spirit of the appended claims.

What is claimed is:

1. A stretchable bracket for placing circuit boards, comprising:
a plurality of upright posts, each upright post comprising a plurality of supporting protrusions arranged along a lengthwise direction of the upright post for supporting the circuit boards; and
a plurality of connecting rods, each two adjacent upright posts being connected via one connecting rod of the plurality of connecting rods, each connecting rod comprising:
a first connecting portion connected to one of the two adjacent posts, the first connecting portion defining a sliding slot, the sliding slot extending along a lengthwise of the connecting rod;
a second connecting portion connected to the other one of the two adjacent posts, the second connecting portion being slidably engaged in the sliding slot.

2. The stretchable bracket as claimed in claim 1, wherein the number of the plurality of upright posts is larger than three.

3. The stretchable bracket as claimed in claim 1, wherein the upright posts and the supporting protrusions are made of electric conductive material, and the supporting protrusions are grounded via the upright posts.

4. The stretchable bracket as claimed in claim 3, wherein each upright post is integrally formed with the supporting protrusions.

5. The stretchable bracket as claimed in claim 1, wherein each of the plurality of upright posts defines a latching hole, and the first connecting portion and the second connecting portion of each connecting rod each have a latching portion engaged in the latching hole of the corresponding adjacent upright post.

6. The stretchable bracket as claimed in claim 5, wherein the latching hole is a through hole extending along the lengthwise direction of the upright post.

7. The stretchable bracket as claimed in claim 5, wherein the latching portions of the first connecting portion and the second connecting portion are arranged at two opposite ends of the connecting rod.

8. The stretchable bracket as claimed in claim 1, wherein one of the first connecting portion and the second connecting portion further defines a sliding groove extending along the lengthwise of the connecting rod, and the other one of the first connecting portion and the second connecting portion comprises an engaging protrusion engaged in and slidable along the sliding groove to prevent the second connecting portion separating from the first connecting portion.

9. The stretchable bracket of claim 8, wherein the sliding groove is defined in the first connecting portion, and the engaging portion is defined in the second connecting portion.

10. The stretchable bracket of claim 1, wherein the first connecting portion comprises a first wall and a second wall, the sliding slot being formed between the first wall and the second wall.
